(19) United States
(12) Patent Application Publication
(10) Pub. No.: US 2010/0224251 A1
(43) Pub. Date: Sep. 9, 2010

(54) METHOD OF MANUFACTURING SOLAR CELL

(76) Inventor: Yasushi Funakoshi, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/668,069

(22) PCT Filed: Jun. 9, 2008
(86) PCT No.: PCT/JP2008/060544

§ 371 Date: May 21, 2010

(30) Foreign Application Priority Data
Jul. 13, 2007 (JP) 2007-184432

(51) Int. Cl. H01L 31/028; H01L 31/18

(52) U.S. Cl. 136/261; 438/57; 438/98; 257/E31.011; 257/E31.001

(57) ABSTRACT

A method of manufacturing a solar cell includes the steps of forming on one main surface of a silicon substrate, a first conductivity type impurity layer and a mask layer lying thereon, applying a pattern of an etching paste capable of etching the mask layer and the first conductivity type impurity layer onto the mask layer, subjecting the silicon substrate to heat treatment such that a partial region of the silicon substrate is exposed by etching away the mask layer and the first conductivity type impurity layer in a region of the pattern of the etching paste, forming a second conductivity type impurity layer in the exposed partial region of the silicon substrate, and removing the mask layer. In addition, a solar cell manufactured with the method of manufacturing a solar cell is provided.

### TECHNICAL HELD

The present invention relates to a method of manufacturing a solar cell, and particularly to a method of manufacturing a solar cell achieving reduction in manufacturing cost by replacing a photolithography process with an application process.

### BACKGROUND ART

In recent years, development of a clean energy source has been demanded in view of a problem of energy resource exhaust and a global environmental problem such as increase in CO₂ in atmosphere. In particular, photovoltaic power generation using solar cells has been developed and put into practical use as a new energy source, and it is still being developed.

Such a solar cell that, in a light-receiving surface of a single-crystal or polycrystalline silicon substrate of one conductivity type, an impurity of a reverse conductivity type is diffused to form a pn junction and electrodes are formed on the light-receiving surface and a back surface of the silicon substrate respectively, has conventionally been mainstream of the solar cell (see Japanese Patent Laying-Open No. 11-17201 (Patent Document 1)). In addition, a solar cell that achieves higher output owing to a back surface field by forming on a back surface of a silicon substrate of one conductivity type, an impurity layer containing an impurity identical in the conductivity type in high concentration has also become common.

Moreover, what is called a back contact solar cell (also referred to as a back electrode solar cell) in which an electrode is not formed on a light-receiving surface of a silicon substrate but a pn junction is formed on its back surface has also been developed (see Japanese Patent Laying-Open No. 11-17201 (Patent Document 1), U.S. Pat. No. 6,998,288 (Patent Document 2), and Japanese Patent Laying-Open No. 2006-332273 (Patent Document 3)). As the back contact solar cell generally does not have an electrode on the light-receiving surface, it is free from shadow loss caused by the electrode, and output higher than in a solar cell having electrodes on the light-receiving surface and the back surface of the silicon substrate respectively can be expected.

In a conventional method of manufacturing a solar cell, a photolithography process or a resist ink is used for forming a p⁺ layer region and an n⁺ layer region on one main surface of a silicon substrate. Therefore, the conventional method of manufacturing a solar cell has suffered from high manufacturing cost, because a resist which is generally expensive is used or the process is complicated.

In addition, a printable etching paste for etching a surface of silicon oxide and silicon nitride based systems and layers thereof and use of this etching paste in a process of manufacturing a solar cell have been proposed (see Japanese National Patent Publication No. 2003-531807 (Patent Document 4)).

Further, a method of manufacturing a back contact solar cell capable of achieving reduction in manufacturing cost by replacing a photolithography process with a printing process has been proposed (see Japanese Patent Laying-Open No. 2007-88254 (Patent Document 5)).

### Patent Document 1: Japanese Patent Laying-Open No. 11-17201

Patent Document 2: U.S. Pat. No. 6,998,288

### Patent Document 3: Japanese Patent Laying-Open No. 2006-332273

### Patent Document 4: Japanese National Patent Publication No. 2003-531807

### Patent Document 5: Japanese Patent Laying-Open No. 2007-88254

### DISCLOSURE OF THE INVENTION

### Problems to be Solved by the Invention

In manufacturing a back contact solar cell, further simplification of a step of forming a diffusion layer has been demanded. Though hydrofluoric acid or phosphoric acid is able to etch a silicon oxide film, a silicon nitride film or the like, it cannot etch a silicon substrate.

From the foregoing, the present invention aims to provide a method capable of manufacturing a solar cell with simplified steps with low cost.

### Means for Solving the Problems

A method of manufacturing a solar cell according to the present invention is characterized by including the steps of: forming on one main surface of a silicon substrate, a first conductivity type impurity layer and a mask layer lying thereon, applying a pattern of an etching paste capable of etching the mask layer and the first conductivity type impurity layer onto the mask layer, subjecting the silicon substrate to heat treatment such that the mask layer and the first conductivity type impurity layer are etched away in a region of the pattern of the etching paste and a partial region of the silicon substrate is exposed, forming a second conductivity type impurity layer in the exposed partial region of the silicon substrate, and removing the mask layer.

Preferably, the pattern of the etching paste occupies 40% or less of an area of the one main surface of the silicon substrate. The etching paste may contain an etching component including at least one of KOH, NaOH and TMAH. Preferably, a temperature for the heat treatment of the silicon substrate is not lower than 150° C. and not higher than 400° C.

The mask layer may include at least any of a silicon oxide film and a silicon nitride film. On the other hand, a BSG film used as an impurity diffusion source for forming the first conductivity type impurity layer may be used as the mask layer. In forming the BSG film, spin-coating with a solvent containing a boron component may be carried out at a revolution speed from 200 to 3000 rpm and thereafter heating at a temperature not lower than 970° C. may be carried out.

The one main surface of the silicon substrate described previously may be a main surface opposite to a solar ray incident side. Subsequent to removal of the mask layer, the steps of forming a passivation film on the one main surface of the silicon substrate, applying a pattern of a second etching paste capable of etching the passivation film onto the passivation film, exposing at least a partial region of the first conductivity type impurity layer and at least a partial region of the second conductivity type impurity layer, in a region of the pattern of the second etching paste, and forming a first electrode in contact with the exposed partial region of the first conductivity type impurity layer and a second electrode in contact with the exposed partial region of the second conductivity type impurity layer may further be included.

In addition, a solar cell according to the present invention is characterized by being manufactured through the steps of forming on one main surface of a silicon substrate, a first conductivity type impurity layer and a mask layer lying thereon, applying a pattern of an etching paste capable of etching the mask layer and the first conductivity type impurity layer onto the mask layer, subjecting the silicon substrate to heat treatment such that the mask layer and the first conductivity type impurity layer are etched away in a region of the pattern of the etching paste and a partial region of the silicon substrate is exposed, forming a second conductivity type impurity layer in the exposed partial region of the silicon substrate, removing the mask layer, forming a passivation film on the one main surface of the silicon substrate, applying a pattern of a second etching paste capable of etching the passivation film onto the passivation film, exposing at least a partial region of the first conductivity type impurity layer and at least a partial region of the second conductivity type impurity layer, in a region of the pattern of the second etching paste, and forming a first electrode in contact with the exposed partial region of the first conductivity type impurity layer and a second electrode in contact with the exposed partial region of the second conductivity type impurity layer.

### EFFECTS OF THE INVENTION

In the method of manufacturing a solar cell according to the present invention, complicated steps of applying a resist layer onto a mask layer, patterning the resist layer (photolithography), curing (heating) the resist layer, etching the mask layer, and removing the resist layer in the conventional art can be replaced with simplified steps of applying an etching paste, etching (heating) and cleaning (washing with water), and manufacturing cost can thus be reduced.

### BRIEF DESCRIPTION OF THE DRAWINGS

FIG. 1(a) shows in a schematic plan view, a back surface of a back contact solar cell by way of example of a solar cell obtained with a manufacturing method according to the present invention, FIG. 1(b) is a schematic cross-sectional view along the line 1B-1B in FIG. 1(a), and FIG. 1(c) shows in a schematic plan view, a variation of the solar cell in FIG. 1(a).

FIG. 2 is a schematic cross-sectional view illustrating an example of the method of manufacturing the back contact solar cell shown in FIGS. 1(a) and 1(b) according to the present invention.

FIG. 3 is a schematic cross-sectional view illustrating a variation of the manufacturing method in FIG. 2.

FIG. 4 is a schematic cross-sectional view showing an example of a floating junction solar cell.

FIG. 5 is a schematic cross-sectional view illustrating an exemplary state of directly applying an alkali-component-containing paste onto a silicon substrate for etching.

FIG. 6 is a schematic cross-sectional view illustrating an exemplary state of applying an alkali-component-containing paste onto a silicon oxide film on the silicon substrate for etching.

FIG. 7 is a photograph of a surface showing an etched state corresponding to FIG. 6(b).

### DESCRIPTION OF THE REFERENCE SIGNS

1 silicon substrate; 2 first diffusion-blocking mask; 3 p⁺ layer; 4a, 4b second diffusion-blocking mask; 5 first etching paste pattern; 6 n⁺ layer; 7 texturing mask; 8 textured structure; 9 passivation film; 9a, 9b contact hole; 10 anti-reflection coating; 11a, 11b electrode; 12 alignment mark; 13 BSG film; 14 PSG film; 22a, 22b n⁺ layer; 23 p⁺ layer; 24 anti-reflection coating; 25 silicon oxide film; and 26, 27 electrode.

### BEST MODES FOR CARRYING OUT THE INVENTION

### First Embodiment

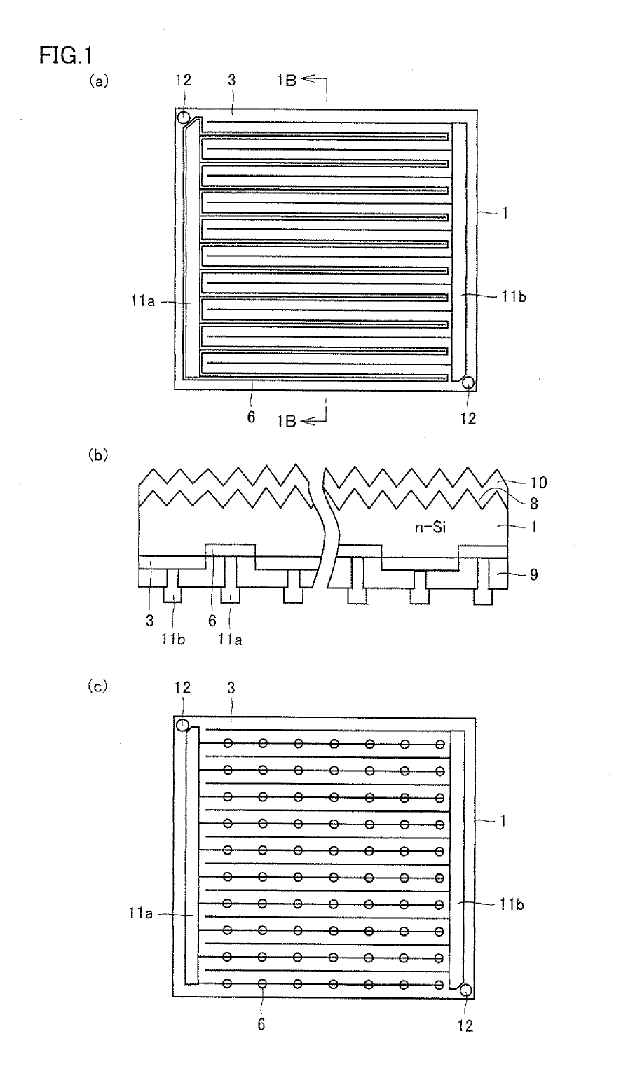

FIG. 1(a) shows in a schematic plan view, a back surface of a back contact solar cell by way of example of a solar cell obtained with a manufacturing method according to the present invention. In addition, FIG. 1(b) is a schematic cross-sectional view along the line 1B-1B in FIG. 1(a). In the drawings of the subject application, it is noted that dimensional relation such as length, width and thickness is modified as appropriate for clarity and simplification of the drawings, and actual dimensional relation is not shown. Namely, the drawings in the subject application are merely schematic. Further, the same or corresponding elements have the same reference characters allotted in the drawings.

In the solar cell in FIG. 1(a), on a back surface of an n-type silicon substrate 1, a p⁺ type impurity layer region 3 and an n⁺ type impurity layer region 6 formed in a comb shape are formed. An electrode for n-type 11a in a comb shape is formed on n⁺ layer region 6, and an electrode for p-type 11b in a comb shape is formed on p⁺ layer region 3 in a manner facing the electrode for n-type.

As shown in FIG. 1(b), a light-receiving surface of silicon substrate 1 is etched so that a textured structure 8 is formed and an anti-reflection coating 10 is formed thereon. A passivation film 9 is formed on the back surface of silicon substrate 1. In addition, n⁺ layer region 6 and p⁺ layer region 3 are alternately formed at a prescribed distance, on the back surface of silicon substrate 1. A pn junction is formed by n-type silicon substrate 1 and p⁺ layer region 3 on the back surface of the substrate. Electrode for p-type 11b is formed on p⁺ layer region 3, and electrode for n-type 11a is formed on the n⁺ layer region.

A schematic plan view in FIG. 1(c) shows a variation of the solar cell in FIG. 1(a). Namely, the solar cell in FIG. 1(c) is different from the solar cell in FIG. 1(a) only in that n⁺ layer region 6 is formed not in a comb shape but in a plurality of dots. In manufacturing such a solar cell as in FIG. 1(c), an amount of an etching paste used in the present invention can be decreased.

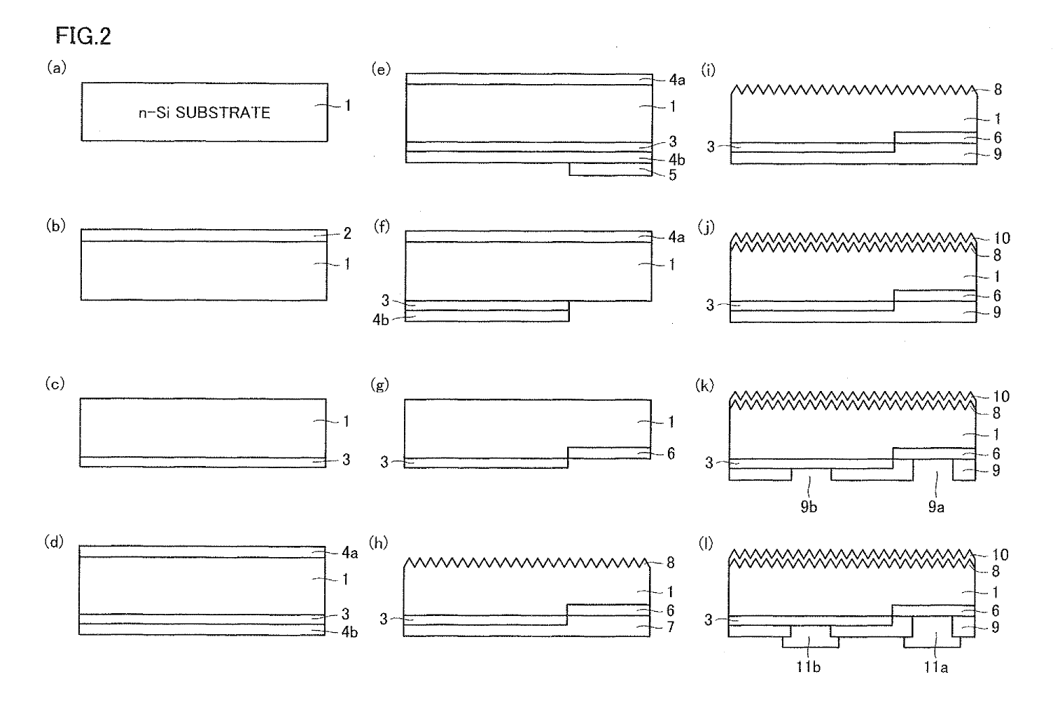

In the schematic cross-sectional views in FIGS. 2(a) to 2(1), an exemplary method of manufacturing the back contact solar cell shown in FIGS. 1(a) and 1(b) according to the present invention is illustrated. For the brevity of illustration, FIGS. 2(a) to 2(1) show that a single n⁺ layer region and a single p⁺ layer region are only formed on the back surface of the silicon substrate, however, actually, a plurality of n⁺ layer regions and a plurality of p⁺ layer regions can naturally be formed.

Initially, as shown in FIG. 2(a), n-type silicon substrate 1 is prepared. Here, for example, polycrystalline silicon, single crystal silicon or the like can be used for silicon substrate 1. In addition, the silicon substrate may be of p-type, and in that case, a pn junction is formed by an n⁺ layer on the back surface of the silicon substrate and the p-type silicon substrate. Though a size and a shape of the silicon substrate are not particularly limited, for example, the silicon substrate can have a thickness not smaller than 100 μm and not greater than 300 μm and have a quadrangular shape of which one side is not shorter than 100 mm and not longer than 150 mm. In addition, in order to improve accuracy of a position of application of an etching paste and a silver paste which will be described later, as shown in FIG. 1(a), two circular alignment marks 12 may be provided on the back surface of the silicon substrate with the use of a laser marker.

Further, for example, a substrate, from which slice damage caused by slicing from an ingot has been eliminated, may be used as silicon substrate 1. Here, such slice damage can be eliminated by etching the surface of the silicon substrate with a mixed acid of a hydrogen fluoride aqueous solution and nitric acid, an alkali aqueous solution of sodium hydroxide etc., or the like.

In FIG. 2(b), a silicon oxide film serving as a first diffusion-blocking mask 2 is formed on a light-receiving surface of silicon substrate 1. The silicon oxide film can be formed, for example, with an atmospheric pressure CVD (chemical vapor deposition) method, application and firing of SOG (spin on glass), or the like. Here, though a thickness of the silicon oxide film is not particularly limited, for example, it can have a thickness not smaller than 100 nm and not greater than 300 nm. Then, boron is diffused into the back surface of the silicon substrate through vapor phase diffusion using BBr₃, to thereby form a p⁺ layer.

In FIG. 2(c), silicon oxide film 2 on the light-receiving surface of silicon substrate 1 and BSG (boron silicate glass) formed together with p⁺ layer 3 formed through boron diffusion in the back surface are removed by using a hydrogen fluoride aqueous solution or the like. It is noted that p⁺ layer 3 may be formed by applying a solvent containing boron to the back surface of silicon substrate 1 followed by heating.

In FIG. 2(d), silicon oxide films 4a and 4b are formed as second diffusion-blocking masks, on the entire surfaces of the light-receiving surface and the back surface of silicon substrate 1, respectively. Though a thickness of the silicon oxide film is not particularly limited, for example, it can have a thickness not smaller than 100 nm and not greater than 300 nm. It is noted that, other than the silicon oxide film, a silicon nitride film, a layered structure of a silicon oxide film and a silicon nitride film, or the like may be used as first and second diffusion-blocking masks 2, 4a and 4b.

In FIG. 2(e), a first etching paste pattern 5 is applied to a part of silicon oxide film 4b on the back surface of silicon substrate 1. More specifically, first etching paste pattern 5 is applied onto silicon oxide film 4b in correspondence with a location where the n⁺ layer region is to be formed. A dispenser, an ink-jet technique, screen printing, roll coater printing, offset printing, or the like may be used as the application method. The first etching paste preferably contains as an etching component, an alkali component capable of etching the silicon substrate, in order to etch the silicon substrate on which second diffusion-blocking mask 4b and the first conductivity type impurity layer are formed, and in particular, it preferably contains potassium hydroxide, sodium hydroxide or TMAH (tetramethylammonium hydroxide), or a mixture thereof. In addition, preferably, the first etching paste contains water, an organic solvent, a thickener, and the like as a component other than the etching component, and its viscosity is adjusted such that it is applicable.

Here, for example, at least one of: alcohols such as isopropyl alcohol and diethylene glycol; ethers such as ethylene glycol monobutyl ether and diethylene glycol monobutyl ether; esters such as 2,2-butoxyethyl acetate and propylene carbonate; ketones such as N-methyl-2-pyrrolidone; and the like may be used as the organic solvent. In addition, for example, at least one of: cellulosics such as ethyl cellulose and sodium carboxymethyl hydroxyethyl cellulose; polyamide resins such as nylon 6; polymers such as polyvinyl pyrrolidone obtained by polymerizing vinyl group; and the like may be used as the thickener.

Preferably, concentration of the etching component contained in the first etching paste is set to 10 to 40 mass %, for the following reasons. As second diffusion-blocking mask 4b composed of silicon oxide and/or silicon nitride smaller in an etching rate than silicon should be etched and p⁺ layer 3 should further be etched, etching tends to be insufficient if the concentration is lower than 10 mass %. If the concentration exceeds 40%, it is likely that viscosity necessary for application using a printing method cannot be obtained.

In FIG. 2(f), silicon substrate 1 to which the first etching paste pattern has been applied is subjected to first heat treatment, so that a part of second diffusion-blocking mask 4b and p⁺ layer 3 where the first etching paste pattern has been applied is etched away.

Here, in order to etch the second diffusion-blocking mask and the p⁺ layer, a heating temperature is particularly important. The silicon oxide film or the silicon nitride film used as the diffusion-blocking mask in the present invention is much lower in the etching rate with respect to an alkali solution than silicon, and it is usually employed also as an etching mask for the alkali solution. In general, etching using the alkali solution is performed in a temperature range not higher than 100° C., however, such a temperature results in a long heating time for etching the silicon oxide film or the silicon nitride film. In some cases, the first etching paste may be denatured during heating and etching may stop before the p⁺ layer is etched. In the present invention, heating to a high temperature, that is impossible with the use of the alkali solution, can be performed owing to use of the etching paste, and second diffusion-blocking mask 4b formed of the silicon oxide film or the silicon nitride film and p⁺ layer 3 can simultaneously and reliably be etched in a short period of time.

Here, the temperature for the first heat treatment is preferably not lower than 150° C. and not higher than 400° C., for the following reasons. When second diffusion-blocking mask 4b is formed of the silicon oxide film and/or the silicon nitride film and when the heating temperature of the first etching paste is lower than 150° C., etching of the silicon oxide film and/or the silicon nitride film having a sufficient thickness as diffusion-blocking mask 4b tends to be insufficient and etching is less likely to reach silicon substrate 1. When the heating temperature exceeds 400° C., first etching paste pattern 5 is likely to burn and stick to the back surface of silicon substrate 1 and subsequent complete removal thereof tends to be difficult.

If the etching component is mainly composed of TMAH, however, the temperature for the first heat treatment is preferably not lower than 150° C. and not higher than 200° C., for the following reasons. When the heating temperature is lower than 150° C., etching tends to be insufficient as in the case of potassium hydroxide or sodium hydroxide. When the heating temperature exceeds 200° C., pyrolysis of TMAH is likely and etching tends to be difficult.

Preferably, the time period for the first heat treatment is not shorter than 30 seconds and not longer than 300 seconds, for the following reasons. When the time period for the first heat treatment is shorter than 30 seconds, it is more likely that the p⁺ layer is not completely etched due to variation in the etching rate caused by temperature distribution in the silicon substrate, even though the temperature for the first heat treatment is set to 400° C. On the other hand, heating for a long time in spite of the temperature for the first heat treatment lower than 400° C. causes denaturation of the first etching paste and removal thereof after heating tends to be difficult. Therefore, the time period for heat treatment of the first etching paste is preferably set to 300 seconds or shorter.

By performing heat treatment under such preferred conditions as described above, second diffusion-blocking mask 4b and the silicon substrate can more reliably be etched and the partial region of p⁺ layer 3 can more reliably be removed. Here, an etching depth is preferably 0.5 to 10 μm. Though depending on a diffusion condition, normally, the p⁺ layer has a depth approximately from several hundred nm to 1 μm. In order to reliably remove the p⁺ layer, etching to a depth greater than an assumed depth of the p⁺ layer is preferred. On the other hand, it is less likely that boron is diffused to a depth beyond 10 μm. Accordingly, etching by 10 μm or more leads to such problems as cracking likely to originate from an etched portion or poor printing performance in a subsequent step, because etching is partial and a height difference becomes too large.

The present invention is characterized by including the steps of forming the second diffusion-blocking mask formed of the silicon oxide film or the silicon nitride film on the silicon substrate on which the first conductivity type impurity-diffused layer has been formed, partially applying the first etching paste thereto followed by heating, and simultaneously etching the second diffusion-blocking mask and the first conductivity type impurity-diffused layer, and such simultaneous etching brings about the following two advantages.

The first advantage is that patterning of a second conductivity type impurity-diffused layer formed on the silicon substrate in the next step can be self-aligned. If the second diffusion-blocking mask is formed after the first conductivity type impurity-diffused layer formed on the silicon substrate is partially removed with the first etching paste, the second diffusion-blocking mask should be formed with highly accurate alignment through etching again, which makes the step complicated.

The second advantage is that a boundary of etching can clearly be delimited by performing etching from above the second diffusion-blocking mask. The alkali component included in the first etching paste is hardly dissolved in the organic solvent and it should be dissolved in water in an amount equal to or more than that of the alkali component. Therefore, it is difficult to increase viscosity or thixotropy of the alkali-component-containing etching paste and blur or dripping thereof is likely at the time of application to the silicon substrate through screen printing or the like.

More specifically, as shown in the schematic cross-sectional view in FIG. 5, when second etching paste 5 is directly applied to silicon substrate 1, which is easily etched by the alkali component, followed by heating (see FIG. 5(a)), etching may occur also in a paste blur portion 5a, which is not a designed pattern on the substrate (see FIG. 5(b)). Paste blur portion 5a itself, however, is thin, and first conductivity type impurity-diffused layer 3 cannot usually completely be etched, which results in an incompletely etched portion 3α. When the second conductivity type impurity-diffused layer is formed in such a state, a leakage current may be generated or a recombination current may increase, which may lower solar cell characteristics.

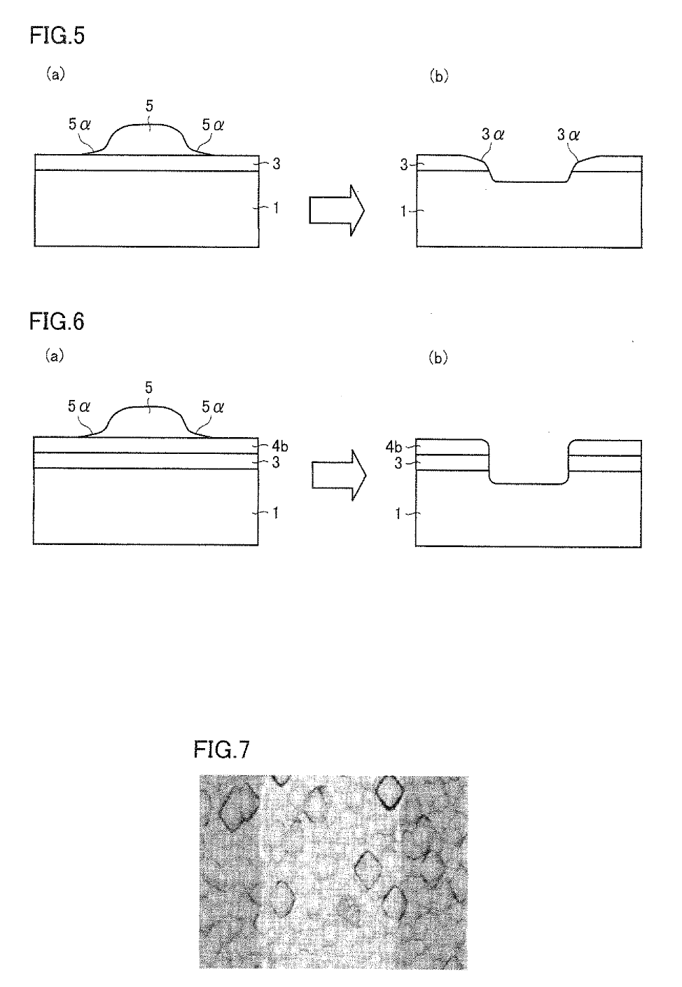

On the other hand, as shown in the schematic cross-sectional view in FIG. 6, when alkali-component-containing etching paste 5 is applied onto second diffusion-blocking mask 4b formed of the silicon oxide film or the silicon nitride film followed by heating (see FIG. 6(a)), second diffusion-blocking mask 4b is not easily etched by the alkali component. Therefore, influence of paste blur portion 5a is little and etching as indicated by a designed pattern can be achieved (see FIG. 6(b)). Thus, by forming the second conductivity type impurity-diffused layer after etching, leakage between the diffusion layers is suppressed and high solar cell characteristics can be expected. Namely, second diffusion-blocking mask 4b can also function as an etching blocking mask in forming the second conductivity type impurity-diffused layer.

FIG. 7 is a photograph showing an upper surface corresponding to FIG. 6(b). In this photograph, silicon oxide film 4b has a thickness around 250 nm. If the thickness of silicon oxide film 4b is varied, a color thereof is varied due to interference of light. It can be seen from the photograph in FIG. 7, however, that the color of silicon oxide film 4b is not varied in the vicinity of the etching boundary and the thickness thereof is not varied.

It is noted that the method of the first heat treatment described previously is not particularly limited and heat treatment can be performed, for example, by using a hot plate, a belt furnace, or an oven.

After the first heat treatment, first etching paste pattern 5 is removed. More specifically, preferably, silicon substrate 1 is immersed in water, the ultrasonic cleaning of silicon substrate 1 is performed and thereafter the back surface of silicon substrate 1 is washed with running water, so that first etching paste pattern 5 is removed. A part of the back surface of silicon substrate 1 is thus exposed. In addition to washing with running water, SC1 cleaning (cleaning with an ammonium hydrogen peroxide solution), SC2 cleaning (cleaning with a hydrochloric acid hydrogen peroxide solution), cleaning with a liquid mixture of sulfuric acid and a hydrogen peroxide solution, cleaning with a dilute hydrogen fluoride aqueous solution, cleaning with a dilute alkali solution, or cleaning with a cleaning liquid containing a surfactant, that is generally known, may also be employed.

In FIG. 2(g), after first etching paste pattern 5 is removed, phosphorus is diffused into an exposed region of the back surface of silicon substrate 1 through vapor phase diffusion using POCl₃, to form n⁺ layer region 6. Thereafter, all of silicon oxide films 4a and 4b present on the light-receiving surface and the back surface of silicon substrate 1 respectively and a PSG (phosphorus silicate glass) film formed together at the time of diffusion of phosphorus are removed with a hydrogen fluoride aqueous solution or the like. It is noted that n⁺ layer region 6 may be formed by applying a phosphorus-containing-solvent to the exposed region of the back surface of silicon substrate 1 followed by heating.

By employing an etching paste for forming an impurity layer region smaller in area in forming a p- or n-type impurity layer region, an amount of used first etching paste can be minimized. Namely, an area of application of the first etching paste pattern is desirably not greater than 50% of the back surface of silicon substrate 1. Regarding a ratio of an area of the p-type and n-type impurity layer regions in the back contact solar cell, according to Japanese Patent Laying-Open No. 2006-332273 (Patent Document 3), it has been found that an area of the p-type impurity layer region is suitably 60% or greater with respect to the n-type silicon substrate. In the method according to the present embodiment as well, by employing etching paste pattern 5 in forming n-type impurity layer region 6 identical in type to silicon substrate 1, an area of application of the first etching paste pattern is preferably 40% or less and more preferably 30% or less. In order to further reduce the amount of used etching paste, n-type impurity layer region 6 may be formed in dots as shown in FIG. 1(c), instead of the comb shape as shown in FIG. 1(a).

In FIG. 2(h), a silicon oxide film serving as a texturing mask 7 is formed on the back surface of silicon substrate 1 and textured structure 8 is formed on the light-receiving surface of silicon substrate 1. Here, silicon oxide film 7 can be formed, for example, with an atmospheric pressure CVD method, application and firing of SOG (spin on glass), or the like. Though a thickness of silicon oxide film 7 is not particularly limited, for example, it can have a thickness not smaller than 300 nm and not greater than 800 nm.

Other than the silicon oxide film, a silicon nitride film, a layered structure of a silicon oxide film and a silicon nitride film, or the like may be used as texturing mask 7. Here, the silicon nitride film can be formed, for example, with a plasma CVD method. Though a thickness of the silicon nitride film is not particularly limited, it can have a thickness not smaller than 60 nm and not greater than 100 nm.

It is noted that textured structure 8 on the light-receiving surface can be formed with etching. For an etchant for that purpose, for example, a liquid obtained by adding isopropyl alcohol to an alkali aqueous solution of sodium hydroxide, potassium hydroxide or the like and heating the solution, for example, to a temperature not lower than 70° C. and not higher than 80° C. can be employed.

In FIG. 2(i), after silicon oxide film 7 is once removed from the back surface of silicon substrate 1 using a hydrogen fluoride aqueous solution or the like, a silicon nitride film to serve as passivation film 9 is formed with the plasma CVD method. Instead of the silicon nitride film, a silicon oxide film formed with dry oxidation (thermal oxidation) or a layered film of a silicon oxide film and a silicon nitride film may be employed as back surface passivation film 9.

In FIG. 2(j), anti-reflection coating 10 formed of a silicon nitride film is formed on the light-receiving surface of silicon substrate 1 with plasma CVD.

In FIG. 2(k), passivation film 9 on the back surface of silicon substrate 1 is partially removed and contact holes 9a and 9b are formed, to thereby expose a part of n⁺ layer region 6 and p⁺ layer region 3. Here, partial removal of silicon nitride film 9 can be achieved by applying a second etching paste pattern to the surface thereof using a screen printing method or the like followed by second heat treatment.

At least one selected from phosphoric acid, hydrogen fluoride, ammonium fluoride, and ammonium bifluoride can be employed as the etching component in the second etching paste. Here, the alkali component is not employed, in order to etch only passivation film 9 but not to etch n-type and p-type impurity layer regions 6 and 3. Preferably, a temperature and a time period for the second heat treatment are set to 200 to 400° C. and 30 to 180 seconds, respectively.

After the second heat treatment in FIG. 2(k), the second etching paste is removed. More specifically, preferably, silicon substrate 1 is immersed in water, the ultrasonic cleaning of silicon substrate 1 is performed and thereafter the back surface of the silicon substrate is washed with running water, so that the second etching paste is removed. N⁺ layer region 6 and p⁺ layer region 3 are thus partially exposed. Here again, in addition to washing with running water, SC1 cleaning, SC2 cleaning, cleaning with a liquid mixture of sulfuric acid and a hydrogen peroxide solution, cleaning with a dilute hydrogen fluoride aqueous solution, cleaning with a dilute alkali solution, or cleaning with a cleaning liquid containing a surfactant, that is generally known, may also be employed.

Finally, as shown in FIG. 2(l), a silver paste is applied to the respective exposed surfaces of n⁺ layer region 6 and p⁺ layer region 3 followed by firing, so that electrode for n-type 11a is formed on n⁺ layer region 6 and electrode for p-type 11b is formed on p⁺ layer region 3. Thus, the back electrode solar cell is completed.

### Second Embodiment

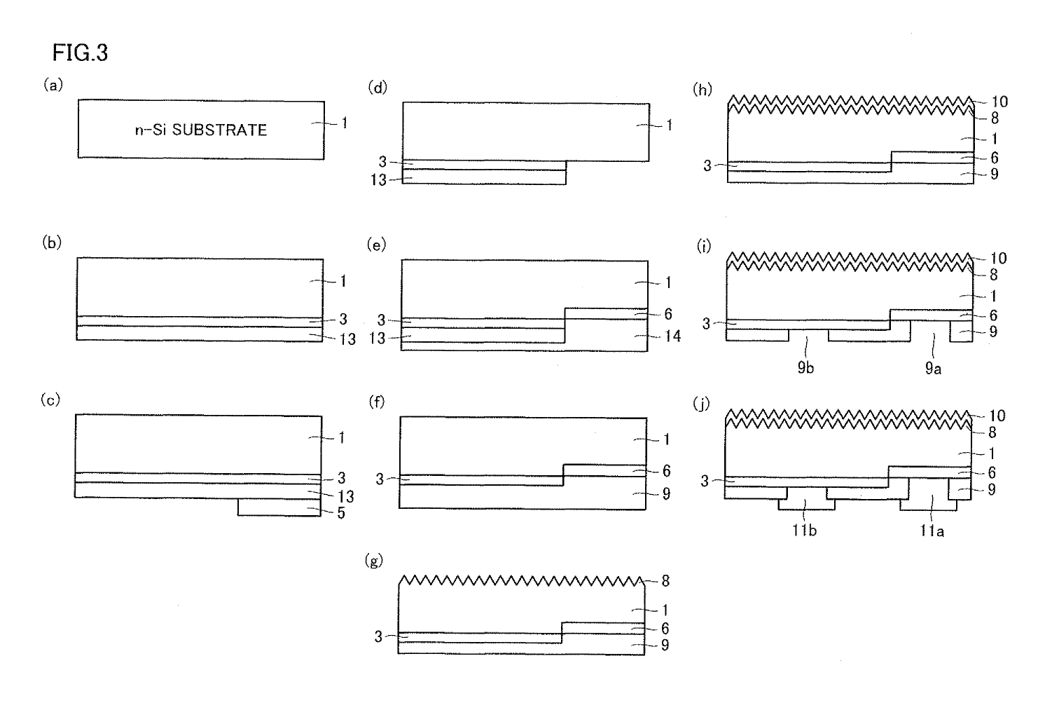

FIGS. 3(a) to 3(j) similar to FIGS. 2(a) to 2(l) illustrate another example of the method of manufacturing a back contact solar cell according to the present invention. Regarding FIGS. 3(a) to 3(j), description of matters clearly achieved as in FIGS. 2(a) to 2(l) will not be repeated.

Initially, in FIG. 3(a), an n-type silicon substrate is prepared as in FIG. 2(a).

In FIG. 3(b), unlike an example where diffusion-blocking mask 2 in FIG. 2(b) is used, p⁺ layer 3 is formed by spin-coating the back surface of silicon substrate 1 with a boron-containing solvent (BSG liquid) layer 13 followed by heating.

P⁺ layer 3 can be formed also through vapor phase diffusion using BBr₃. According to the method of the present embodiment, however, as the diffusion-blocking mask is not formed on the light-receiving surface, the p⁺ layer tends to be formed also on the light-receiving surface if vapor phase diffusion is used, and it is likely that a flat portion is produced in forming a texture on the light-receiving surface in a subsequent step. In addition, in texturing etching, etching away of the p⁺ layer on the light-receiving surface tends to be incomplete. Therefore, preferably, p⁺ layer 3 is formed on the back surface of silicon substrate 1 by diffusing boron from the BSG liquid into the back surface thereof.

On the other hand, even in using the BSG liquid, depending on a heating condition, the boron component contained in the BSG liquid may diffuse in vapor phase and the p⁺ layer may be formed on the light-receiving surface. Such a p⁺ layer, however, is extremely lower in boron concentration than layer 3 on the back surface of which formation is essentially intended, and it does not affect texturing etching and the p⁺ layer remaining on the light-receiving surface after texturing etching will not adversely affect solar cell characteristics.

According to the method of the present embodiment, BSG film 13 formed at the time of formation of p⁺ layer 3 through heating is used as a mask in subsequent diffusion of an n-type impurity. Therefore, for the purpose of controlling a thickness of the BSG film as well, p⁺ layer 3 is preferably formed from the BSG liquid. In order to obtain a sufficient thickness of BSG film 13 to serve as the diffusion-blocking mask in a subsequent step, the revolution speed in spin-coating is preferably set to 3000 rpm or lower. In order to avoid wrap-around of the perimeter of silicon substrate 1 by the BSG liquid, however, the revolution speed is preferably set to 200 rpm or higher.

In addition, in order to use BSG film 13 as the diffusion-blocking mask, a film not only sufficiently thick but also dense is desirably formed. To that end, silicon substrate 1 is preferably heated at a temperature not lower than 970° C. Namely, where spin-coating at the revolution speed exceeding 3000 rpm and thermal diffusion at a temperature lower than 970° C. are employed, the solar cell characteristics tend to be low and a function as a mask for n-type impurity diffusion tends to be insufficient.

In FIG. 3(c), as in FIG. 2(e), first etching paste pattern 5 is applied onto BSG film 13 on the back surface of silicon substrate 1.

In FIG. 3(d), as in FIG. 2(f), silicon substrate 1 is subjected to the first heat treatment, so that BSG film 13 and p⁺ layer 3 in the region of first etching paste pattern 5 are partially etched away. Cleaning after this first heat treatment can also be performed as in the first embodiment.

In FIG. 3(e), the diffusion-blocking mask is not formed on the light-receiving surface of silicon substrate 1 but the back surface thereof is spin-coated with a phosphorus-containing solvent (PSG liquid) followed by heating, so that n⁺ layer region 6 is formed on the exposed surface of the back surface of silicon substrate 1.

Though n⁺ layer region 6 may be formed through vapor phase diffusion using POCl₃, it is more preferably formed through diffusion from the applied PSG liquid. When n⁺ layer region 6 is formed through vapor phase diffusion using POCl₃ as in the case of p-type impurity diffusion described previously, the layer unintentionally formed on the light-receiving surface tends to be higher in concentration and thicker than in employing the PSG liquid. Then, in texturing etching, the n⁺ layer may partially remain without being completely removed, and therefore, diffusion using PSG liquid 14 is more preferred for forming n⁺ layer region 6.

The heating temperature in diffusion of the n-type impurity is preferably set to 750 to 850° C., for the following reasons. When the temperature is lower than 750° C., concentration of phosphorus that diffuses into silicon substrate 1 is low and in-plane distribution is great, which results in poor solar cell characteristics. On the other hand, when the temperature exceeds 850° C., BSG film 13 does not tend to sufficiently function as the diffusion-blocking mask. The revolution speed of the substrate in application of PSG liquid 14 is not particularly limited, however, it can be set to 3000 to 5000 rpm.

In FIG. 3(f), BSG film 13 and PSG film 14 on the back surface of silicon substrate 1 are removed with a hydrogen fluoride aqueous solution or the like and thereafter a silicon nitride film serving as passivation film 9 is formed on the back surface with the plasma CVD method. For simplification of the process, silicon nitride film 9 can also be used as a film for protecting the back surface of silicon substrate 1 in subsequent texturing etching. When used as the protection film, silicon nitride film 9 should be thicker than when it is used as the normal passivation film, and it preferably has a thickness from 70 to 150 nm.

Instead of the silicon nitride film, a silicon oxide film formed by thermal oxidation of the silicon substrate or a layered film of a silicon oxide film and a silicon nitride film may also be employed as back surface passivation film 9. If a single layer of the silicon oxide film is to serve as both of passivation film 9 and the protection film, in order to achieve a thickness sufficient as the protection film in texturing etching, an extremely long process time is required only for the oxide film formed by thermal oxidation. Therefore, preferably, only the silicon oxide film to be used as the passivation film is formed by thermal oxidation and thereafter the silicon oxide film having a thickness from 400 to 1000 nm is formed as the texturing mask with the atmospheric pressure CVD method. It is not necessary to remove the silicon oxide film formed with the atmospheric pressure CVD method after texturing etching.

In FIG. 3(g), as in FIG. 2(h), textured structure 8 is formed on the light-receiving surface of silicon substrate 1.

In FIG. 3(h), as in FIG. 2(j), anti-reflection coating 10 formed of the silicon nitride film is formed on the light-receiving surface of silicon substrate 1 with plasma CVD.

In FIG. 3(i), as in FIG. 2(k), back surface passivation film 9 is partially removed and contact holes 9a and 9b are formed, so that n⁺ layer region 6 and p⁺ layer region 3 are thus partially exposed.

Finally, in FIG. 3(j), as in FIG. 2(l), electrode for n-type 11a is formed on the exposed surface of n^{j} layer 6 and electrode for p-type 11b is formed on the exposed surface of the p⁺ layer region. Thus, in the present second embodiment, the back electrode solar cell can be manufactured with the method in which the process is further simplified as compared with the first embodiment.

As described previously, in applying the etching paste pattern and the silver paste pattern, application accuracy can be improved by using alignment mark 12 as shown in FIG. 1(a).

As described above, according to the present invention, manufacturing cost for the back electrode solar cell can significantly be reduced by replacing the photolithography process with the application process.

In the embodiments above, a back contact solar cell has been described, however, the present invention is applicable to all solar cells including a floating junction type other than the back contact type, in which both of an n layer (n⁺ layer) region and a p layer (p⁺ layer) region are formed on one surface of the silicon substrate.

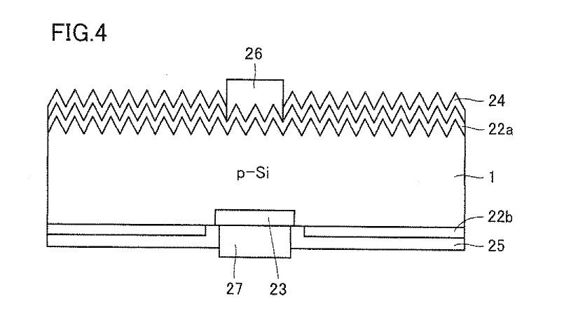

For reference purpose, FIG. 4 shows an exemplary floating junction solar cell in a schematic cross-sectional view. In this solar cell, n⁺ layers 22a and 22b are formed on the light-receiving surface and the back surface of p-type silicon substrate 1, respectively. N⁺ layer 22a on the light-receiving surface is covered with a silicon nitride film 24, while n⁺ layer 22b on the back surface is covered with a silicon oxide film 25. On the light-receiving surface of silicon substrate 1, an electrode for n-type 26 is connected to n⁺ layer 22a through an opening provided in silicon nitride film 24. On the other hand, on the back surface, an electrode for p-type 27 is connected to a p⁺ layer region 23 formed in silicon substrate 1 through an opening provided in silicon oxide film 25.

### EXAMPLES

### Example 1

A solar cell according to Example 1 was fabricated in correspondence with the first embodiment described above. Therefore, present Example 1 is also described with reference to FIGS. 2(a) to 2(l). Initially, a slice damage layer of an n-type silicon wafer having one side of 100 mm long and a thickness around 200 μm was removed with a sodium hydroxide solution, to prepare n-type silicon substrate 1 (see FIG. 2(a)).

Then, a silicon oxide film having a thickness of 250 nm was formed as first diffusion-blocking mask 2 on the light-receiving surface of silicon substrate 1 with atmospheric pressure CVD (see FIG. 2(b)).

Through vapor phase diffusion using BBr₃ in atmosphere at 950° C. for 60 minutes, boron was diffused into the back surface of silicon substrate 1 to form p⁺ layer 3. Thereafter, silicon oxide film 2 on the light-receiving surface of silicon substrate 1 and the BSG (boron silicate glass) film formed together with boron diffusion were all removed by using a hydrogen fluoride aqueous solution (see FIG. 2(c)).

In succession, silicon oxide films 4a and 4b each having a thickness of 250 nm were formed on the entire surfaces of the light-receiving surface and the back surface of silicon substrate 1 as the second diffusion-blocking masks, respectively, with atmospheric pressure CVD (see FIG. 2(d)). Then, first etching paste pattern 5 was applied onto silicon oxide film 4b on the back surface of silicon substrate 1 with the screen printing method (see FIG. 2(e)). Here, etching paste pattern 5 was applied in a comb shape, and the area of application was 30% with respect to the entire back surface of silicon substrate 1. An etching paste containing potassium hydroxide as the etching component, obtained by mixing N-methyl-2-pyrrolidone and sodium carboxymethyl hydroxyethyl cellulose in a potassium hydroxide aqueous solution, and adjusted to an appropriate viscosity was employed as the first etching paste. Here, concentration of potassium hydroxide in the first etching paste was 30 mass %.

Thereafter, silicon substrate 1 to which first etching paste pattern 5 was applied was subjected to first heat treatment by heating with the use of a hot plate at 250° C. for 120 seconds, so that silicon oxide film 4b and p⁺ layer 3 in the region where first etching paste pattern 5 was applied were etched. It had been confirmed that heat treatment under these conditions achieved etching of silicon substrate 1 to a thickness of approximately 1.5 μm. Namely, it was confirmed that the total thickness of p⁺ layer 3 was etched away. After the first heat treatment, silicon substrate 1 was subjected to ultrasonic cleaning in water for 5 minutes and the back surface of the substrate was washed with running water for 5 minutes, so that first etching paste pattern 5 was removed and 30% of the area of the back surface of silicon substrate 1 was exposed (see FIG. 2(f)).

Thereafter, through vapor phase diffusion using POCl₃ at 900° C. for 30 minutes, phosphorus was diffused into the exposed region of the back surface of silicon substrate 1 to form n⁺ layer region 6. Then, silicon oxide films 4a and 4b on the light-receiving surface and the back surface of silicon substrate 1 respectively and the PSG (phosphorus silicate glass) film formed together at the time of phosphorus diffusion were removed by using a hydrogen fluoride aqueous solution (see FIG. 2(g)).

Thereafter, a silicon oxide film having a thickness of 700 nm was formed on the back surface of silicon substrate 1 as texturing mask 7 with the atmospheric pressure CVD method. Then, an etchant obtained by adding a small amount of isopropyl alcohol to a sodium hydroxide aqueous solution and heating the solution to 80° C. was employed to etch the light-receiving surface of silicon substrate 1, to thereby form textured structure 8 (see FIG. 2(h)).

In succession, after silicon oxide film 7 was once removed from the back surface of silicon substrate 1 using a hydrogen fluoride aqueous solution or the like, a silicon nitride film to serve as passivation film 9 was formed on the back surface of silicon substrate 1 with the plasma CVD method (see FIG. 2(i)). On the other hand, a silicon nitride film to serve as anti-reflection coating 10 was formed on the light-receiving surface of silicon substrate 1 with the plasma CVD method (see FIG. 2(j)).

In addition, the second etching paste pattern was applied onto silicon oxide film 9 on the back surface of silicon substrate 1 with the screen printing method. The second etching paste contained phosphoric acid as the etching component and viscosity thereof was adjusted with the thickener so that screen printing can be performed. Here, concentration of phosphoric acid in the second etching paste was 30 mass %. Thereafter, silicon substrate 1 to which the second etching paste pattern was applied was subjected to second heat treatment on the hot plate at 300° C. for 90 seconds, so that a partial region of the silicon nitride film covered with the second etching paste pattern on the back surface of silicon substrate 1 was etched. After the second heat treatment, ultrasonic cleaning and washing with running water were performed under the conditions the same as described previously, so that circular contact holes 9a and 9b each having a diameter around 100 μm were formed in silicon oxide film 9 on the back surface of silicon substrate 1 and layer region 6 and p⁺ layer region 3 were partially exposed (see FIG. 2(k)).

Finally, a silver paste was applied to the respective exposed surfaces of n⁺ layer region 6 and p⁺ layer region 3 followed by firing, so that electrode for n-type 11a was formed on the exposed surface of n⁺ layer region 6 and electrode for p-type 11b was formed on exposed p⁺ layer region 3.

The back contact solar cell according to present Example 1 thus fabricated was irradiated with AM 1.5 light emitted from a solar simulator at intensity of 1 kW/m² and output characteristics thereof were measured. Then, a short-circuit current density (Jsc) of 40.05 mA/cm², an open circuit voltage (Voc) of 0.631 V, a fill factor (F.F) of 0.745, and photoelectric conversion efficiency (TO of 18.81% were obtained.

### Example 2

A solar cell according to Example 2 was fabricated in correspondence with the second embodiment described previously. Therefore, present Example 2 is also described with reference to FIGS. 3(a) to 3(j). Initially, a slice damage layer of an n-type silicon wafer having one side of 100 mm long and a thickness around 200 μm was removed with a sodium hydroxide solution to prepare n-type silicon substrate 1 (see FIG. 3(a)).

Then, the back surface of silicon substrate 1 was spin-coated with a boron-component-containing solvent at the revolution speed of 1000 rpm followed by drying. Thereafter, heating at 1000° C. for 50 minutes was performed and boron was diffused, so that p⁺ layer 3 was formed on the back surface of silicon substrate 1. BSG (boron silicate glass) film 13 formed on the back surface of silicon substrate 1 at the time of boron diffusion remained without being removed (see FIG. 3(b)).

In succession, as in Example 1 (see FIG. 2(e)), in present Example 2 as well, first etching paste pattern 5 was applied onto BSG film 13 on the back surface of silicon substrate 1 using the first etching paste the same as in Example 1 with the screen printing method (see FIG. 3(c)).

Thereafter, as in Example 1 (see FIG. 2(f), in present Example 2 as well, silicon substrate 1 to which first etching paste pattern 5 was applied was subjected to first heat treatment by heating with the use of a hot plate at 250° C. for 120 seconds, so that BSG film 13 and p⁺ layer 3 on the back surface of silicon substrate 1 in the region where first etching paste pattern 5 was applied were etched (see FIG. 3(d)). In present Example 2 as well, it had been confirmed that silicon substrate 1 was etched by approximately 1.5 μm, and it was confirmed that the total thickness of p⁺ layer 3 was etched. Thereafter, as in Example 1, in present Example 2 as well, first etching paste pattern 5 after the first heat treatment was removed and 30% of the area of the back surface of silicon substrate 1 was exposed.

Then, the back surface of silicon substrate 1 was spin-coated with a phosphorous-component-containing solvent at the revolution speed of 4000 rpm followed by drying. Thereafter, heating at 820° C. for 40 minutes was performed and phosphorous was diffused, so that n⁺ layer region 6 was formed in the exposed region of the back surface of silicon substrate 1. Thereafter, BSG film 13 on the back surface of silicon substrate 1 and PSG (phosphorous silicate glass) film 14 formed together at the time of diffusion of phosphorous (see FIG. 3(e)) were all removed by using the hydrogen fluoride aqueous solution.

In succession, a silicon nitride film to serve as passivation film 9 was formed on the back surface of silicon substrate 1 with the plasma CVD method (see FIG. 3(f)). Silicon nitride film 9 was formed to a relatively large thickness of 120 nm, in order to serve also as the texturing mask.

Then, as in Example 1 (see FIG. 2(h)), in present Example 3 as well, textured structure 8 was formed on the light-receiving surface of silicon substrate 1 (see FIG. 3(g)).

Thereafter, as in Example 1 (see FIG. 2(j)), in present Example 3 as well, silicon nitride film 10 to serve as the anti-reflection coating was formed on the light-receiving surface with the plasma CVD method (see FIG. 3(h)).

In succession, as in Example 1 (see FIG. 2(k)), in present Example 3 as well, the second etching paste pattern the same as in Example 1 was applied onto silicon nitride film 9 on the back surface of silicon substrate 1 with the screen printing method. Thereafter, the silicon substrate to which the second etching paste was applied was subjected to second heat treatment with the use of the hot plate at 300° C. for 90 seconds, so that silicon nitride film 9 in the region where the second etching paste was applied was etched. After the second heat treatment, ultrasonic cleaning and washing with running water were performed under the conditions the same as described previously, so that circular contact holes each having a diameter around 100 μm were formed in silicon nitride film 9 on the back surface of silicon substrate 1 and n⁺ layer region 6 and p⁺ layer region 3 were partially exposed (see FIG. 3(i)).

Finally, as in Example 1 (see FIG. 2(l)), in present Example 2 as well, a silver paste was applied to the respective exposed surfaces of n⁺ layer region 6 and p⁺ layer region 3 followed by firing, so that electrode for n-type 11a was formed on the exposed surface of n⁺ layer region 6 and electrode for p-type 11b was formed on the exposed surface of p⁺ layer region 3.

The back contact solar cell according to present Example 2 thus fabricated was irradiated with AM 1.5 light emitted from a solar simulator at intensity of 1 kW/m² and output characteristics thereof were measured as in Example 1. Then, a short-circuit current density (Jsc) of 39.67 mA/cm², an open circuit voltage (Voc) of 0.629 V, a fill factor (F.F) of 0.700, and photoelectric conversion efficiency (η) of 17.46% were obtained.

It is noted that effects of the present invention can naturally similarly be obtained even when the p-type and the n-type are interchanged in the embodiments and examples above.

It should be understood that the embodiments and examples described above are illustrative and non-restrictive in every respect. The scope of the present invention is defined by the terms of the claims, and is intended to include any modifications within the scope and meaning equivalent to the terms of the claims.

### INDUSTRIAL APPLICABILITY

According to the present invention, a method enabling manufacturing of a solar cell with simplified steps with low cost can be provided.

1. A method of manufacturing a solar cell, comprising the steps of:
forming on one main surface of a silicon substrate, a first conductivity type impurity layer and a mask layer lying thereon;
applying a pattern of an etching paste capable of etching said mask layer and said first conductivity type impurity layer onto said mask layer;
subjecting said silicon substrate to heat treatment such that said mask layer and said first conductivity type impurity layer are etched away in a region of said pattern of said etching paste and a partial region of said silicon substrate is exposed;
forming a second conductivity type impurity layer in exposed said partial region of said silicon substrate; and
removing said mask layer.

2. The method of manufacturing a solar cell according to claim 1, wherein
said pattern of said etching paste occupies 40% or less of an area of said one main surface of said silicon substrate.

3. The method of manufacturing a solar cell according to claim 1, wherein
said etching paste contains an etching component including at least one of KOH, NaOH and TMAH.

4. The method of manufacturing a solar cell according to claim 3, wherein
a temperature for said heat treatment is not lower than 150° C. and not higher than 400° C.

5. The method of manufacturing a solar cell according to claim 1, wherein
said mask layer includes at least any of a silicon oxide film and a silicon nitride film.

6. The method of manufacturing a solar cell according to claim 1, wherein
a BSG film used as an impurity diffusion source for forming said first conductivity type impurity layer is also used as said mask layer.

7. The method of manufacturing a solar cell according to claim 6, wherein
in forming said BSG film, spin-coating with a solvent containing a boron component is carried out at a revolution speed from 200 to 3000 rpm and thereafter heating at a temperature not lower than 970° C. is carried out.

8. The method of manufacturing a solar cell according to claim 1, wherein
said one main surface of said silicon substrate is a main surface opposite to a solar ray incident side.

9. The method of manufacturing a solar cell according to claim 8, comprising, subsequent to removal of said mask layer, the steps of:
forming a passivation film on said one main surface of said silicon substrate;
applying a pattern of a second etching paste capable of etching said passivation film onto said passivation film;
exposing at least a partial region of said first conductivity type impurity layer and at least a partial region of said second conductivity type impurity layer, in a region of said pattern of said second etching paste; and
forming a first electrode in contact with exposed said partial region of said first conductivity type impurity layer and a second electrode in contact with exposed said partial region of said second conductivity type impurity layer.

10. A solar cell, manufactured through the steps of:
forming on one main surface of a silicon substrate, a first conductivity type impurity layer and a mask layer lying thereon;
applying a pattern of an etching paste capable of etching said mask layer and said first conductivity type impurity layer onto said mask layer;
subjecting said silicon substrate to heat treatment such that said mask layer and said first conductivity type impurity layer are etched away in a region of said pattern of said etching paste and a partial region of said silicon substrate is exposed;
forming a second conductivity type impurity layer in exposed said partial region of said silicon substrate;
removing said mask layer;
forming a passivation film on said one main surface of said silicon substrate;
applying a pattern of a second etching paste capable of etching said passivation film onto said passivation film;
exposing at least a partial region of said first conductivity type impurity layer and at least a partial region of said second conductivity type impurity layer, in a region of said pattern of said second etching paste; and
forming a first electrode in contact with exposed said partial region of said first conductivity type impurity layer and a second electrode in contact with exposed said partial region of said second conductivity type impurity layer.
